(19) United States
(12) Patent Application Publication
(10) Pub. No.: US 2012/0269985 A1
(43) Pub. Date: Oct. 25, 2012

(54) ATMOSPHERIC FILM-COATING METHOD

(75) Inventors: Yih-Ming SHYU, TAINAN CITY (TW); Yan-Gen CHEN, TAICHUNG CITY (TW); Shih-Ming HUANG, CHANGHUA COUNTY (TW); Chun-Chia YEH, TAINAN CITY (TW); Pei-Lin CHEN, TAINAN CITY (TW)

(73) Assignee: CREATING NANO TECHNOLOGIES, INC., TAINAN CITY (TW)

(21) Appl. No.: 13/294,184

(22) Filed: Nov. 11, 2011

(30) Foreign Application Priority Data
Apr. 21, 2011 (TW) 100113923

(51) Int. Cl. C23C 16/44; C23C 16/04

(52) U.S. Cl. 427/534; 427/248.1

(57) ABSTRACT

An atmospheric film-coating method is described, which includes the following steps. A substrate is provided. A gasification step is performed on a film coating solution to form a plurality of film coating vapor molecules. The film coating vapor molecules are deposited on a surface of the substrate to form the film.

### RELATED APPLICATIONS

This application claims priority to Taiwan Application Serial Number 100113923, filed Apr. 21, 2011, which is herein incorporated by reference.

### FIELD OF THE INVENTION

The present invention relates to a method for manufacturing a film, and more particularly to a method for coating a film in an atmospheric way.

### BACKGROUND OF THE INVENTION

As portable electronic devices are progressively popularized, protection requirement to outer surfaces of the portable electronic devices are increasingly enhanced to maintain the appearances of the portable electronic devices. Currently, in order to protect the outer surfaces of the portable electronic devices, an anti-smudge film such as an anti-fingerprint film, is usually coated on the outer surface. For example, a surface of a touch screen of a popular touch electronic device is usually coated with an anti-fingerprint film to keep display quality and operation sensitivity in good condition after being touched and rubbed many times.

In general, the film covering the surface has properties of good anti-smudge, anti-fingerprint, smooth, hydrophobic, oleo-phobic and transparent. In addition, the film must have strong adhesion to an outer surface of the device to prolong the use life.

Currently, there are four main methods for coating a film on a surface of a substrate. The first method is a vacuum evaporation method. In the method, the coating is heated underneath the substrate in a vacuum chamber to gasify to arise and adhere to the lower surface of the substrate to form a film. However, the coating method needs to vacuum the evaporation chamber, so that the process time is increased, the throughput is poor, and the method is unsuitable for a substrate surface, which needs to be continuously evaporated.

The second method is a dipping coating method. In the method, the substrate is dipped in a film coating solution to make it coated with the coating after taking it out. However, with regard to the coating of a continuous substrate, the required apparatus would be large, so that the method is unsuitable for the continuous substrate.

The third method is a spray coating method. In the method, the film coating is sprayed directly toward the surface of the substrate to form a film. However, most of the coating spray contacts the surface of the substrate before being gasified, so that droplets drip on the surface of the substrate. As a result, the coated film has poor uniformity.

The fourth method is a brush coating method, which directly coats a film onto the surface of the substrate by a brush. However, the coating method usually causes a reduplicated coating phenomenon between two adjacent brushing areas, so that the film has poor uniformity.

### SUMMARY OF THE INVENTION

Therefore, one aspect of the present invention is to provide an atmospheric film-coating method, which can coat a film under an atmospheric environment, so that the throughput can be highly increased.

Another aspect of the present invention is to provide an atmospheric film-coating method, which can coat films onto continuous substrates effectively.

Still another aspect of the present invention is to provide an atmospheric film-coating method which can coat film on the surface of a big amount of substrate rapidly and uniformly.

According to the aforementioned purposes, the present invention provides an atmospheric film-coating method, which includes the following steps. A substrate is provided. A gasification step is performed on a film coating solution to form a plurality of film coating vapor molecules. The film coating vapor molecules are deposited on a surface of the substrate to form the film.

According to an embodiment of the present invention, the film coating solution includes film coating molecules and a solvent, and the solvent includes a high volatile liquid and/or water.

According to another embodiment of the present invention, the film is an anti-smudge film, and a material of the film coating molecules includes F—C—Si hydrocarbon compounds, perfluorocarbon-Si (PFC—Si) hydrocarbon compounds, F—C—Si alkane compounds, PF—Si alkane compounds or PF—Si alkane ether compounds.

According to still another embodiment of the present invention, a vapor pressure of the high volatile liquid is higher than a vapor pressure of the water at a room temperature. The high volatile liquid is selected from a group consisting of alcohol, ether, alkane, ketone, benzene, fluorine-containing alcohol, fluorine-containing ether, fluorine-containing alkane, fluorine-containing ketone and fluorine-containing benzene.

According to further another embodiment of the present invention, the film is a PEDOT:PSS film, and the film coating molecules includes PEDOT:PSS molecules.

According to yet another embodiment of the present invention, the film is an ITO film, and the film coating solution includes a plurality of indium and tin precursors. In addition, after the step of depositing film coating vapor molecules, the atmospheric film-coating method further includes supplying energy to the indium and tin precursors to make the indium and tin precursors react to form the ITO film.

According to still further another embodiment of the present invention, the gasification step includes using a nebulization element. The nebulization element may include an ultrasonic nebulization element, a heating evaporation nebulization element, a high-pressure gas jet element or a nozzle nebulization element.

According to still yet another embodiment of the present invention, before the gasification step, the atmospheric film-coating method further includes cleaning and treating the surface of the substrate by using a plasma to form a plurality of functional groups on the surface of the substrate. The functional groups may include a plurality of hydroxyl functional groups, a plurality of hydronitrogen functional groups and/or a plurality of dangling bonds.

According to still yet another embodiment of the present invention, before the gasification step, the atmospheric film-coating method further includes using a protective cover to cover the substrate, and the gasification step is performed within the protective cover.

According to still yet another embodiment of the present invention, before the step of depositing the film coating vapor molecules, the atmospheric film-coating method further includes convecting the film coating vapor molecules within the protective cover.

### BRIEF DESCRIPTION OF THE DRAWINGS

The foregoing aspects and many of the attendant advantages of this invention are more readily appreciated as the same become better understood by reference to the following detailed description, when taken in conjunction with the accompanying drawings, wherein:

FIG. 1 is a flowchart showing an atmospheric film-coating method in accordance with an embodiment of the present invention; and

FIG. 2A through FIG. 2C are process cross-sectional views of an atmospheric film-coating method in accordance with an embodiment of the present invention.

### DETAILED DESCRIPTION OF THE PREFERRED EMBODIMENT

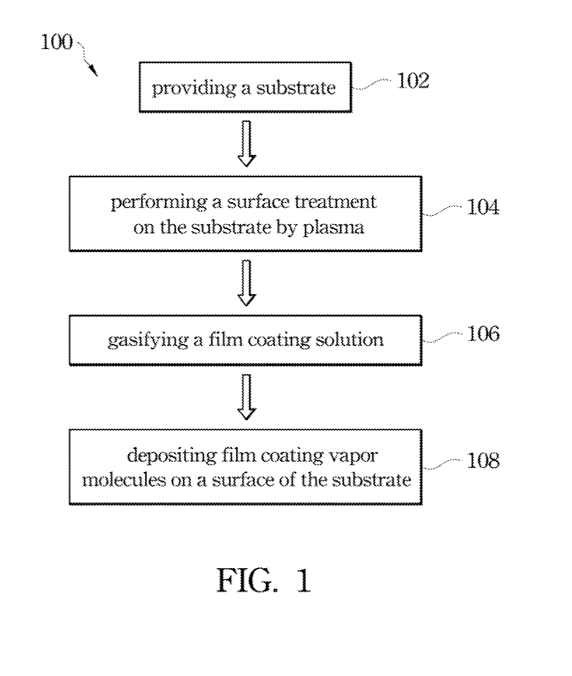

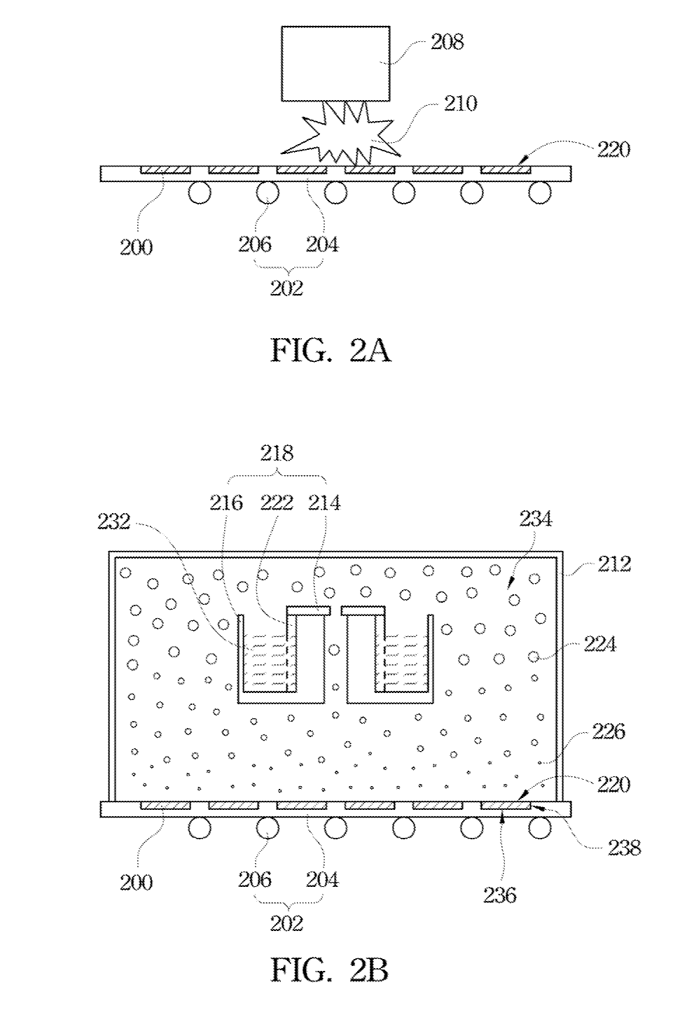

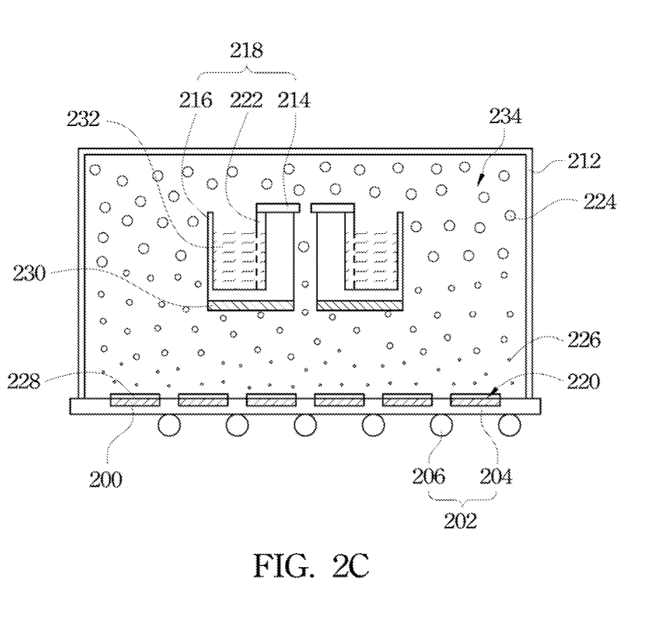

FIG. 1 is a flowchart showing a method for coating a film atmospherically in accordance with an embodiment of the present invention, and FIG. 2A through FIG. 2C are process cross-sectional views of an atmospheric film-coating method in accordance with an embodiment of the present invention. The method for coating a film atmospherically of the present embodiment can be applied in the manufacturing of an anti-smudge film, an ITO film and a PEDOT:PSS film.

As shown in FIG. 1, in an atmospheric film-coating method 100 of the present embodiment, a substrate 200 may be firstly provided, as stated in a step 102. The substrate 200 may be a protective glass, a plastic substrate, a tempered glass or a metal substrate.

In one embodiment, when performing the step 102 to provide the substrate 200, one or more substrates 200 may be disposed on a conveyer 202. In the embodiment shown in FIG. 2A, the conveyer 202 is composed of a conveying strap 204 and rollers 206, and the substrates 200 are arranged on the conveying strap 204. In other embodiments, the substrate may be a continuous substrate, and the conveyer may be a conveying device, which can drive the continuous substrate, such as two rollers respectively disposed on both front side and rear side of a coating device to support and drive the continuous substrate forward. In this case, a conveying strap is not needed for carrying the substrate.

In the present embodiment, when a film 228 (referring to FIG. 2C) is coated, according to process requirements, a plasma device 208 may be selectively used to produce a plasma 210, and the plasma 210 may be used to perform a cleaning and surface modification treatment on a surface 220 of the substrate 200 to activate the surface 220 of the substrate 200, as stated in a step 104 in FIG. 1. In one embodiment, after the surface 220 of the substrate 200 is activated by the plasma 210, a plurality of functional groups are formed on the surface 220 of the substrate 200. In one example, the plasma 210 may be produced by using working gas such as nitrogen gas, argon gas, oxygen gas or air. After the surface treatment is performed by the plasma 210, the functional groups formed on the surface 220 of the substrate 200 can be bonded with film coating vapor molecules 226, such as hydroxyl functional groups and/or hydronitrogen functional groups. In one embodiment, the functional groups formed on the surface 220 of the substrate 200 may further include dangling bonds, which can be bonded with the film coating vapor molecules 226.

In one embodiment, the surface modification treatment may be performed on the surface 220 of the substrate 200 by atmospheric plasma or low-pressure plasma. For example, the atmospheric plasma may be an atmospheric plasma jet (or plasma torch), a corona discharge, a gliding arc discharge, a dielectric barrier discharge (DBD) plasma or an atmospheric glow discharge plasma, and the low-pressure plasma may be a vacuum plasma. In addition, the plasma device 208 may be an atmospheric plasma device, a low-pressure plasma device or an electromagnetically coupled plasma device, for example. It is worthy of note that in the present embodiment, the cleaning and activating of the surface 220 of the substrate 200 is preferably performed by the atmospheric plasma for an operation consistency with a subsequent atmospheric coating procedure to reduce process time.

After the surface treatment step 104 of the substrate 200 is completed, a step 106 is immediately performed. In one embodiment, in the step 106, a nebulization device 218 may be disposed over the surface 220 of the substrate 200, and a protective cover 212 is used to cover the substrate 200, so that a reactive chamber 234 can be defined by the protective cover 212 and the conveying strap 204 of the conveyer 202. Then, as shown in FIG. 2B, under an atmospheric environment, a film coating solution 232 is nebulized by the nebulization device 218 over the surface 220 of the substrate 200 within the reactive chamber 234, so as to form a film coating mist 224 over the surface 220 of the substrate 200.

A nebulization element may be used to nebulize the film coating solution 232. The nebulization element may be an ultrasonic nebulization element, a heating evaporation nebulization element, a high-pressure gas jet element or a nozzle nebulization element, for example. In the embodiment illustrated in FIG. 2B, the nebulization device 218 may include a coating-receiving device 216, an ultrasonic nebulization vibration sheet 214 and a coating-conducting element 222. That is the nebulization element used in the embodiment in FIG. 2B is the ultrasonic nebulization vibration sheet 214.

In the nebulization device 218, the film coating solution 232 is carried in the coating-receiving device 216. The ultrasonic nebulization vibration sheet 214 is disposed on a top portion of one side of the coating-receiving device 216. The coating-conducting element 222 is connected between the film coating solution 232 in the coating-receiving device 216 and the ultrasonic nebulization vibration sheet 214 to convey the film coating solution 232 from the coating-receiving device 216 to the ultrasonic nebulization vibration sheet 214. After the ultrasonic vibration performed by the ultrasonic nebulization vibration sheet 214, the film coating solution 232 can be nebulized to the film coating mist 224. Subsequently, after a solvent in the film coating mist 224 is volatilized rapidly, the film coating mist 224 is changed to the film coating vapor molecules 226.

In some embodiments, the ultrasonic nebulization vibration sheet 214 may float on the film coating solution 232, and it is unnecessary for the nebulization device 218 to include a coating-conducting element 222. The coating-conducting element 222 may be a cotton sliver or a conducting pipe, for example.

The film coating solution 232 may include film coating molecules and a solvent. In one embodiment, when an anti-smudge film is coated, the film coating solution 232 uses a solution including anti-smudge coating molecules. The material of the anti-smudge coating molecules may include F—C—Si hydrocarbon compounds, PFC—Si hydrocarbon compounds, F—C—Si alkane compounds, PF—Si alkane compounds or PF—Si alkane ether compounds. In another embodiment, when an ITO film is coated, the film coating solution 232 uses a solution including indium and tin precursors. In still another embodiment, when a PEDOT:PSS film is coated, the film coating solution 232 uses a solution including PEDOT:PSS molecules.

In addition, the solvent of the film coating solution 232 may include a high volatile liquid, water, or a liquid composed of a mixture of the high volatile liquid and water. The high volatile liquid is in a liquid state at a room temperature, has a stable chemical structure, volatility and a low boiling point, is transparent and colorless, and has no obvious harm to creatures. In a preferred embodiment, a vapor pressure of the high volatile liquid is higher than a vapor pressure of water at a room temperature, and the high volatile liquid may be selected from a group consisting of alcohol, ether, alkane, ketone, benzene, fluorine-containing alcohol, fluorine-containing ether, fluorine-containing alkane, fluorine-containing ketone and fluorine-containing benzene.

When the nebulization element, such as the ultrasonic nebulization vibration sheet 214, is used to nebulize the film coating solution 232, the high volatile solvent can drive the larger film coating molecules, so that it can facilitate the nebulization of the film coating solution 232 to convert into the film coating mist 224.

In other embodiments, a heater may be further used to heat the film coating mist 224 formed by the nebulization device 218 to accelerate the conversion from the film coating mist 224 to the film coating vapor molecules 226. For example, when the solvent of the film coating solution 232 is water or other liquid, which is not a high volatile liquid, the heater may be used to facilitate the conversion from the film coating mist 224 to the film coating vapor molecules 226.

After the film coating solution 232 was nebulized within the reactive chamber 234, the forming film coating mist 224 spreads within the reactive chamber 234. As stated in a step 108 in FIG. 1, the solvent in the film coating mist 224 is volatilized easily, and the film coating molecules are heavier, so that the film coating mist 224 spread within the reactive chamber 234 is gasified to form the film coating vapor molecules 226 after the solvent is volatilized. The film coating vapor molecules 226 fall down and are deposited on the surface 220 of the substrate 200 to form the film 228, as shown in FIG. 2C. In some embodiments, the film 228 may be an anti-smudge film or a PEDOT:PSS film. The PEDOT:PSS film is typically used in an organic light emitting diode (OLED) or an organic solar cell.

In an embodiment of coating an ITO film, after the film coating vapor molecules 226 including indium and tin precursors are deposited on the surface 220 of the substrate 200, energy may be provided to the indium and tin precursors pre-coated on the surface 220 of the substrate 200 by heating, plasma or laser, to make the indium and tin precursors react to form an ITO film.

In a preferred embodiment of the present invention, the surface 220 of the substrate 200 has functional groups after being activated, so that the film coating vapor molecules 226 in the film coating mist 224 adhere to the surface 220 of the substrate 200 in an anisotropic manner and has a condensation reaction with the functional groups on the surface 220 of the substrate 200. As a result, a strong adhesive force is formed between the formed film 228 and the surface 220 of the substrate 200.

In another embodiment of the present invention, a convection device, such as a fan, may be selectively disposed within the reactive chamber 234 before the deposition of the film coating vapor molecules 226 according to process requirements, and the convection device is used to distribute the film coating vapor molecules 226 within the reactive chamber 234 more uniformly. If a surface 236 and/or a side surface 238 of the substrate 200 do not adhere to the conveying strap 204 entirely, the film coating vapor molecules 226 can be deposited on the surface 220, the surface 236 and/or the side surface 238 of the substrate 200 simultaneously to coat the film 228 on the surface 220, the surface 236 and/or the side surface 238. All of the surface 220, the surface 236 and the side surface 238 of the substrate 200 can be coated with the film 228 by gasifying the film coating solution 232 to form the film coating vapor molecules 226 within the reactive chamber 234. Furthermore, as shown in FIG. 2C, a supporter 230 may be disposed within the reactive chamber 234 to support the nebulization device 218.

In the present embodiment, an evaporation apparatus composed of several nebulization devices 218 may be used to coat films on several substrates 200 arranged in a line, a row or an array simultaneously. Furthermore, in the present invention, the coating of the film 228 is performed atmospherically, so that the film coating molecules can be largely, rapidly, effectively and uniformly coated on the surface of the substrate 200.

In addition, one feature of the present embodiment of the present invention is that, the nebulization of the film coating solution is performed over the substrate to be treated, so that the spraying direction of the film coating mist formed after the film coating solution is nebulized is not toward the substrate directly. Therefore, after the gasification of the film coating solution is complete, the gasified film coating solution molecules contacts with the surface of the substrate. Accordingly, it can prevent a droplet phenomenon from occurring on the surface of the substrate to increase the coating uniformity of the film.

In other embodiments of the present invention, the nebulization of the film coating solution can be performed on regions other than the region over the substrate to be treated. For example, the nebulization of the film coating solution may be performed underneath the substrate, and the film coating mist is then guided by a conduit. With the conduit, the film coating vapor molecules converted from the film coating mist during a conducting process can be guided to a region of the substrate where needs to be coated with a film, so as to form the film on the demanding region of the substrate.

According to the aforementioned embodiments of the present invention, one advantage of the present invention is that the present invention uses an atmospheric evaporation method to coat a film, so that procedures of lowering pressure and vacuum-pumping are avoided, thereby greatly reducing the apparatus cost and increasing the throughput.

According to the aforementioned embodiments of the present invention, another advantage of the present invention is that the present invention uses an atmospheric evaporation method to coat a film, so that the present invention can efficiently coat the film on a continuous substrate.

According to the aforementioned embodiments of the present invention, still another advantage of the present invention is that the nebulization step and the gasification step of a film coating solution are performed atmospherically, so that the present invention can largely, rapidly, effectively and uniformly coat a film on one single or more surfaces of a substrate to be treated.

As is understood by a person skilled in the art, the foregoing preferred embodiments of the present invention are illustrative of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. An atmospheric film-coating method, including:
providing a substrate;
performing a gasification step on a film coating solution to form a plurality of film coating vapor molecules; and
depositing the film coating vapor molecules on a surface of the substrate to form the film.

2. The atmospheric film-coating method according to claim 1, wherein the gasification step includes using a nebulization element, and the nebulization element includes an ultrasonic nebulization element, a heating evaporation nebulization element, a high-pressure gas jet element or a nozzle nebulization element.

3. The atmospheric film-coating method according to claim 1, wherein the film coating solution includes film coating molecules and a solvent, and the solvent includes a high volatile liquid and/or water.

4. The atmospheric film-coating method according to claim 3, wherein the film is an anti-smudge film, and a material of the film coating molecules includes F—C—Si hydrocarbon compounds, PFC—Si hydrocarbon compounds, F—C—Si alkane compounds, PF—Si alkane compounds or PF—Si alkane ether compounds.

5. The atmospheric film-coating method according to claim 3, wherein a vapor pressure of the high volatile liquid is higher than a vapor pressure of the water at a room temperature, and the high volatile liquid is selected from a group consisting of alcohol, ether, alkane, ketone, benzene, fluorine-containing, alcohol, fluorine-containing ether, fluorine-containing alkane, fluorine-containing ketone and fluorine-containing benzene.

6. The atmospheric film-coating method according to claim 3, wherein the film is a PEDOT:PSS film, and the film coating molecules includes PEDOT:PSS molecules.

7. The atmospheric film-coating method according to claim 3, wherein the film is an ITO film, and the film coating solution includes a plurality of indium and tin precursors.

8. The atmospheric film-coating method according to claim 7, after the step of depositing film coating vapor molecules, further including supplying energy to the indium and tin precursors to make the indium and tin precursors react to form the ITO film.

9. The atmospheric film-coating method according to claim 1, wherein the substrate includes a protective glass, a plastic substrate, a tempered glass or a metal substrate.

10. The atmospheric film-coating method according to claim 1, before the gasification step, further including cleaning and treating the surface of the substrate by using a plasma to form a plurality of functional groups on the surface of the substrate, and the functional groups include a plurality of hydroxyl functional groups, a plurality of hydronitrogen functional groups and/or a plurality of dangling bonds.

11. The atmospheric film-coating method according to claim 10, wherein the plasma is an atmospheric plasma or a low-pressure plasma.

12. The atmospheric film-coating method according to claim 1, before the gasification step, further including using a protective cover to cover the substrate, and the gasification step is performed within the protective cover.

13. The atmospheric film-coating method according to claim 12, before the step of depositing the film coating vapor molecules, further including convecting the film coating vapor molecules within the protective cover.
